(19) United States
(12) Patent Application Publication
(10) Pub. No.: US 2018/0148828 A1
(43) Pub. Date: May 31, 2018

(54) APPARATUS AND METHOD FOR QUANTIFYING THE AMOUNT OF EVAPORATION DEPOSITION OF A SOLID SUBSTANCE

(71) Applicant: NATIONAL CHUNG-SHAN INSTITUTE OF SCIENCE AND TECHNOLOGY, TAOYUAN CITY (TW)

(72) Inventors: TE-JU CHUNG, TAOYUAN CITY (TW); WEN-CHIEH LI, TAOYUAN CITY (TW); SHIH-CHANG LIANG, TAOYUAN CITY (TW); CHAO-NAN WEI, TAOYUAN CITY (TW); CUO-YO NI, TAOYUAN CITY (TW); HUI-YUN BOR, TAOYUAN CITY (TW)

(21) Appl. No.: 15/641,330

(22) Filed: Jul. 5, 2017

(30) Foreign Application Priority Data
Nov. 25, 2016 (TW) 105138747

(51) Int. Cl. C23C 14/24; C23C 14/54

(52) U.S. Cl. CPC C23C 14/243; C23C 14/541

(57) ABSTRACT

In an apparatus for quantifying the amount of evaporation deposition of a solid substance and its method, the apparatus is connected to a reaction chamber, and a solid substance to be evaporated, a heating source and a load cell are disposed in a heating chamber. The load cell is for detecting the weight of the solid substance, and the reduced weight of the solid substance to be evaporated per unit time is equal to the mass flow of the reaction gas, so that the status of the reaction gas can be known by the weight simultaneously. When the solid substance is heated to a state to form the reaction gas, the heating chamber reaches a saturated vapor pressure greater than a vacuum background pressure of the reaction chamber, the reaction gas continues to flow along the pipeline stably towards the reaction chamber to manufacture a thin film.

### CROSS-REFERENCE TO RELATED APPLICATIONS

This non-provisional application claims priority under 35 U.S.C. § 119(a) on Patent Application No(s). 105138747 filed in Taiwan, R.O.C. on Nov. 25, 2016, the entire contents of which are hereby incorporated by reference.

### FIELD OF INVENTION

The present invention relates to the field of evaporation deposition, in particular to an apparatus and method for quantifying the amount of evaporation deposition of a solid substance and its method, and when a solid substance is used as an evaporation deposition material, the evaporation deposition state can be confirmed and controlled simultaneously to manufacture high-quality thin films.

### BACKGROUND OF INVENTION

### 1. Description of the Related Art

Deposition process is mainly divided into two methods, and one is liquid forming, and the other one is vapor deposition. By its name, we can see that evaporation deposition refers to a process of introducing a gas to be evaporated into a reactant chamber, so that the gas to be evaporated is combined with a reactant to achieve the film deposition effect. The quality and uniformity of the thin film manufactured by vapor deposition are determined by the condition whether or not the gas is reacted stably during the process.

Vapor deposition is often applied in the manufacturing process of solar cells such as a copper indium gallium selenide (CIGS) solar cell which is a solar cell composed of Group I-III-VI2 elements. Since the CIGS solar cell has a very high absorption coefficient, an excellent semiconductor property, and the property of being manufactured with different hardness of substrates, the CIGS solar cell is a solar cell with high potential and competiveness in the related industry.

Wherein, the absorption layer of the CIGS solar cell is manufactured by selenization/sulfurization reaction process, and the reaction gas such as H₂Se or H₂S is a mainstream reaction gas. In the gaseous selenium/sulfur chemical reaction process, a gas flow meter is provided for passing H₂Se or H2S gas into the reaction chamber in the reaction process to supply a fixed quantity of reaction gas. After the reactant chamber reaches a specific pressure, the reactant chamber is heated to maintain a stable and uniform chemical reaction of the reactant and the reaction gas in order to manufacture a good-quality CIGS or CIGSS absorption layer.

However, the gaseous H₂Se or H₂S encounters an important issue in the industrial application. Since H₂Se or H₂S is a chemical synthetic gas produced by passing hydrogen gas into liquefied selenium element at a high temperature of 500-700° C. for bubbling and then reacted and synthesized before it is outputted from a duct, and introducing the H₂Se or H₂S gas not doped with the reacting H₂ gas to a condensation separator for separating pure H₂ and condensing and collecting H₂Se or H₂S, and storing these gases together with low-temperature high-pressure liquid carbon dioxide in a gas cylinder, therefore the manufacturing cost is very high. In addition, the H₂Se or H₂S gas has the toxic, flammable, and highly corrosive properties and becomes a flammable poisonous chemical gas of an explosive mixture after it is mixed with air. Particularly, the selenium (Se) compound has a very strong toxicity, and the exposure limit is 0.05 ppm, and thus incurring a high cost for setting up a higher industrial safety environment and filtering and recycling the poisonous gas for the production line.

In addition to the aforementioned drawbacks, the use of gaseous H₂Se or H₂S also has the following problems:

1. The temperature required for a selenization/sulfurization reaction process is approximately 500-600° C., and H₂Se or H₂S is highly corrosive, so that related components in the reactant chamber may be reacted or corroded, and a higher equipment maintenance cost is needed.

2. The material cost of gaseous H₂Se or H₂S is very high. Taking the properties of the reaction gas, the flow, and the change of internal pressure of the reactant chamber into consideration, the reaction gas used for a general selenium/sulfur chemical reaction process is usually diluted and mixed with an inert gas for the chemical reaction process. The distribution of H₂Se or H₂S will no longer be controlled easily after the inert gas is introduced into the reactant chamber, and H₂Se or H₂S just occupies approximately 10% of the total gas content of the reactant chamber after the inert gas is introduced, so that the chemical reaction process takes a very long time up to tens of hours to produce a good-quality CIGS or CIGSS absorption layer, and thus seriously lowering the overall production capacity, and additional costs are incurred to invest for equipments in order to improve the production capacity.

3. To adopt the gaseous H₂Se or H₂S chemical reaction process, the reaction gas at the temperature of 500-600° C. will be decomposed into gas molecules of many different forms, and the gas molecules of these forms do not have any recycle value, and thus also incurring a high process cost.

Taking the process equipment maintenance and the environmental and industrial safety into consideration, the process of using gaseous H₂Se or H₂S as the gas in the selenization/sulfurization reaction process to manufacture the CIGS or CIGSS absorption layer definitely incurs a high cost and a low recyclability and lacks of environmental protection concept. Therefore, how to prepare a stable and uniform distribution of the film is the problem to be overcome simultaneously, especially in the need to use corrosive, toxic and other dangerous element of gas, bit also need more safe and environmentally friendly process program.

### 2. Summary of the Invention

Therefore, it is a primary objective of the present invention to provide an apparatus for quantifying the amount of evaporation deposition of a solid substance and a method thereof, and the reaction gas status of the film deposition and using the solid substance as the evaporation deposition material in the process can be known simultaneously, and the stability of the reaction gas can be maintained, so that the reaction gas can be adjusted according to the process requirements to manufacture a highly uniform and stable high-quality thin film.

To achieve the aforementioned and other objectives, the present invention discloses an apparatus for quantifying the amount of evaporation deposition of a solid substance, connected to a reaction chamber and provided for performing an evaporation deposition process of the substance therein, and the reaction chamber has a vacuum background pressure therein, and the apparatus for quantifying the amount of evaporation deposition of a solid substance comprising: a heating chamber, connected to the reaction chamber through a pipeline; a solid substance to be evaporated, disposed in the heating chamber; a heating source, installed in the heating chamber, and provided for heating the solid substance to be evaporated to evaporate and form a reaction gas, and flowing the reaction gas to the reaction chamber through the pipeline; and a load cell, installed outside the heating chamber, for carrying the solid substance to be evaporated and simultaneously detecting the weight of the solid substance to be evaporated, wherein the weight of the solid substance to be evaporated and reduced per unit time is equal to the mass flow of the reaction gas; wherein, when the solid substance to be evaporated is heated to a vapor state to form the reaction gas, the heating chamber has a saturated vapor pressure greater than the vacuum background pressure, so that the reaction gas continues to flow along the pipeline towards the reaction chamber to perform an evaporation deposition of the substrate, and the load cell simultaneously detects a mass change of the solid substance to be evaporated to effectively quantify a gas mass flow of the reaction gas formed after the solid substance to be evaporated is evaporated, and control the reaction gas flow flowing into the reaction chamber and the film deposition effect. The process conditions can be controlled simultaneously, and the reaction gas can be maintained stable for the evaporation deposition process to prevent a non-uniform distribution of compositions of the manufactured thin film and produce a high-quality thin film effectively.

To achieve the aforementioned and other objectives, the present invention discloses a method for quantifying the amount of evaporation deposition, for supplying a stable reaction gas to a reaction chamber to perform an evaporation deposition process of a substrate in the reaction chamber, and the reaction chamber having a vacuum background pressure, comprising the steps of: providing a heating chamber having a heater and a crucible for carrying a solid substance to be evaporated, and the heating chamber having a load cell installed outside the heating chamber, and the load cell being coupled to the crucible in the heating chamber through a vacuum bellow for measuring the mass of the solid substance to be evaporated, and the heating chamber being coupled to the reaction chamber through a pipeline; the heating the crucible by the heater, such that the solid substance to be evaporated is evaporated to form the reaction gas, and when the interior of the heating chamber reaches a saturated vapor pressure greater than the vacuum background pressure, so that the reaction gas continues to flow along the pipeline towards the reaction chamber to perform an evaporation deposition of the substrate, and the load cell continues measuring the mass of the solid substance to be evaporated to ensure the generation speed of the reaction gas and the speed of the evaporation deposition can meet requirements.

The present invention discloses the apparatus for quantifying the amount of evaporation deposition of a solid substance further comprising a proportion regulating valve installed at the pipeline for regulating the mass flow of the reaction gas passing into the reaction chamber. Adjustments are made to cope with different process requirements and conditions, and an immediate measurement function of the load cell in integrated, so that the reduced weight of the solid substance to be evaporated simultaneously shows whether or not the reaction gas enters into the reaction gas according to the proportion set by the proportion regulating valve.

To prevent the heating chamber from being affected by the heating source to increase the temperature, or the heat of the heating source from being conducted excessively to the heating chamber, or affecting the effect of heating the solid substance to be evaporated, the heating chamber has a thermal insulation layer disposed therein for isolating the heat of the heating source from conducting to the heating chamber.

Moreover, the heating source includes a crucible and a heater, and the crucible is provided for containing the solid substance to be evaporated, and the heater is installed at the outer side of the crucible for heating the solid substance to be evaporated to evaporate the solid substance to be evaporated to form the reaction gas.

Preferably, to ensure the solid substance to be evaporated can obtain a high stability of heating in the heating process, the load cell is connected to a crucible in the heating chamber through a vacuum bellow, so that the heating chamber can achieve anti-leakage effect and produce a micro negative pressure vacuum.

To confirm the saturated vapor pressure anytime, the heating chamber further comprising a manometer for detecting saturated vapor pressure of the heating chamber, however it can backtrack and control the evaporation deposition state of the reaction gas immediately, so that the saturated vapor pressure is maintained to be greater than the vacuum background pressure.

To confirm the reaction pressure of the reaction chamber anytime, the apparatus further comprising a gas pressure control valve installed at the reaction chamber for adjusting a vacuum background pressure of the reaction chamber, so that the sample can be provided for the reaction under a fixed vacuum background pressure.

In a preferred embodiment of the present invention, a method for quantifying the amount of evaporation deposition is disclosed, wherein a stable vapor is supplied to a reaction chamber, and a substrate undergoes an deposition process in the reaction chamber, and the reaction chamber has a vacuum background pressure, characterized in that a solid substance to be evaporated, a heating source and a heating chamber are disposed in the reaction chamber, and a load cell is installed outside the reaction chamber, and the load cell is coupled to a crucible in the heating chamber through a vacuum bellow, and the heating chamber is coupled to the reaction chamber through a pipeline; the heating source heats up and evaporates the solid substance to be evaporated to form a reaction gas, and the load cell is provided for carrying and simultaneously detecting the weight of the solid substance to be evaporated, wherein the reduced weight of the solid substance to be evaporated per unit time is equal to the mass flow of the reaction gas; when the solid substance to be evaporated is evaporated to form the reaction gas, the heating chamber reaches a saturated pressure greater than the vacuum background pressure, so that the reaction gas continues to stably flow along the pipeline towards the reaction chamber to perform an evaporation deposition of the substrate, and the load cell effectively quantifies the gas mass flow of the reaction gas formed by evaporating the solid substance to be evaporated, and a proportion regulating valve installed at the pipeline and a gas pressure control valve installed in the reaction chamber control the mass and flow of the reaction gas to ensure the reaction gas to flow stably towards the reaction chamber. Through the method, the status of forming the reaction gas by using the solid substance as the evaporation deposition material can be controlled effectively in the evaporation deposition process, and the reaction gas can flow stably towards the reaction chamber for a chemical reaction.

Wherein the pipeline further has a proportion regulating valve for regulating the mass flow of the reaction gas passing into the reaction chamber. Adjustments are made to cope with different process requirements and conditions, and an immediate measurement function of the load cell in integrated, so that the reduced weight of the solid substance to be evaporated simultaneously shows whether or not the reaction gas enters into the reaction gas according to the proportion set by the proportion regulating valve.

Moreover, the reaction chamber further has a gas pressure control valve for adjusting a vacuum background pressure of the reaction chamber. After the inert gas such as nitrogen is passed into and mixed with the reaction gas, an adjustment is made automatically according to different reaction pressure requirements, and the apparatus can ensure achieve a constant state of the vacuum background pressure in the reaction chamber in a long time of operation.

As the same, in order to prevent the heating chamber from being affected by the heating source to increase the temperature, or the heat of the heating source from being conducted excessively to the heating chamber, or affecting the effect of heating the solid substance to be evaporated, the heating chamber has a thermal insulation layer disposed therein for isolating the heat of the heating source from conducting to the heating chamber.

In a preferred embodiment of the present invention, the heating source includes a crucible and a heater, and the crucible is provided for containing the solid substance to be evaporated, and the heater is installed at the outer side of the crucible for heating the solid substance to be evaporated to evaporate the solid substance to be evaporated to form the reaction gas.

Furthermore, in order to confirm a saturated vapor pressure of the heating chamber anytime, the apparatus further comprises a manometer installed at the heating chamber for detecting the weight of the solid substance to be evaporated.

In a preferred embodiment of the present invention, the apparatus further comprises a control unit for detecting and controlling the operation of the apparatus for quantifying the amount of evaporation deposition of a solid substance.

In summation of the description above, the present invention discloses an apparatus and method for quantifying the amount of evaporation deposition of a solid substance, wherein the load cell is provided for simultaneously detecting the weight variation of the solid substance to be evaporated to achieve the effect of quantifying the mass flow of the reaction gas in the process and the saturated vapor pressure is set to be greater than the vacuum background pressure, so that the reaction gas naturally flows towards the reaction chamber and can maintain its stability, and the manufactured thin film will have the features of excellent composition uniformity and high quality. The present invention further uses the proportion regulating valve to control the mass flow of the reaction gas and integrates the load cell and uses the reduced weight of the solid substance to be evaporated to simultaneously reflect whether or not the reaction gas flows into the reaction chamber according to the setting of the proportion regulating valve, so that to cope with the process requirements, the reaction gas is adjusted. Finally, the gas pressure control valve is integrated to control the vacuum background pressure of the reaction chamber to control the process conditions effectively to ensure the film deposition quality.

The above summary and the following detailed description and overview all to be able to further explain the way, function and result of the present invention has been achieve the intended purpose. And other objects and advantages related to the present invention will be set forth in the following description and the accompanying drawings.

### BRIEF DESCRIPTION OF THE DRAWINGS

FIG. 1 is a block diagram showing the flow of a preferred embodiment of the present invention;

FIG. 2 is a schematic view of an apparatus of a preferred embodiment of the present invention;

FIG. 3 is a graph of reduced weight versus time of a solid substance to be evaporated at different set values of a proportion regulating valve in accordance with a preferred embodiment of the present invention;

FIG. 4 is a graph of diffusion depth of a solid substance to be evaporated versus time during the process of preparing thin films in accordance with a preferred embodiment of the present invention; and

FIG. 5 is a schematic view of the reproducibility of the proportion S/(Se+S) during the preparation of thin films in accordance with a preferred embodiment of the present invention.

### DESCRIPTION OF THE PREFERRED EMBODIMENTS

Embodiments of the present invention will now be described by way of specific examples, those skilled in the art will readily appreciate the other advantages and effects of the present invention as disclosed in this specification. The above and other objects, features and advantages of this disclosure will become apparent from the following detailed description taken with the accompanying drawings. And the terms of directions like top, bottom, left, right, front or back, is the reference directions of the accompanying drawings. So that the terms of directions are used to description, not to limit the way of the present invention.

In a conventional manufacturing method of thin films, a gaseous material is introduced to perform a film deposition directly, and the conventional manufacturing method has many uncontrollable factors which may lower the quality of the thin film, particularly in the process of manufacturing a solar cell absorption layer. To overcome the drawbacks of the prior art, the inventor of the present invention provides an evaporation deposition process including the steps of heating the solid substance to evaporate into a gas and introducing the gas into a reactant chamber to perform an evaporation deposition process, so as to further comply with the requirements of environmental protection and high-safety process. However, the process of heating the solid substance and using its vapor for the chemical film deposition can overcome the drawbacks of the prior art that introduces the reaction gas into the reactant chamber by a gas flow meter, such that the solid substance cannot use the gas flow meter to effectively control the Moore concentration of the vapor passing into the reactant chamber per unit time, and the vapor entering into the reaction chamber cannot be known accurately, particularly when the manufacturing temperature is higher than the vaporization temperature of the solid substance, the situation is more obvious. Therefore, the reaction vapor used in the process cannot be controlled easily since the mass of the solid substance cannot be quantified effectively, and the distribution of compositions of the manufactured thin film is non-uniform, and the quality of the manufactured thin film is reduced. In addition, when the manufacturing temperature and reaction time rose, and the solid substance may switch to the volatile phase gradually and fail to form the vapor by heating, so that the compositional depth of the manufactured thin film is non-uniform, and the amount of certain specific elements may be too low. To improve the mastery of the process when the solid substance is used as an evaporation deposition material. The present invention provides an apparatus for quantifying the amount of evaporation deposition of a solid substance and its method, so that the thin film manufactured by the solid substance features a stable and uniform quality.

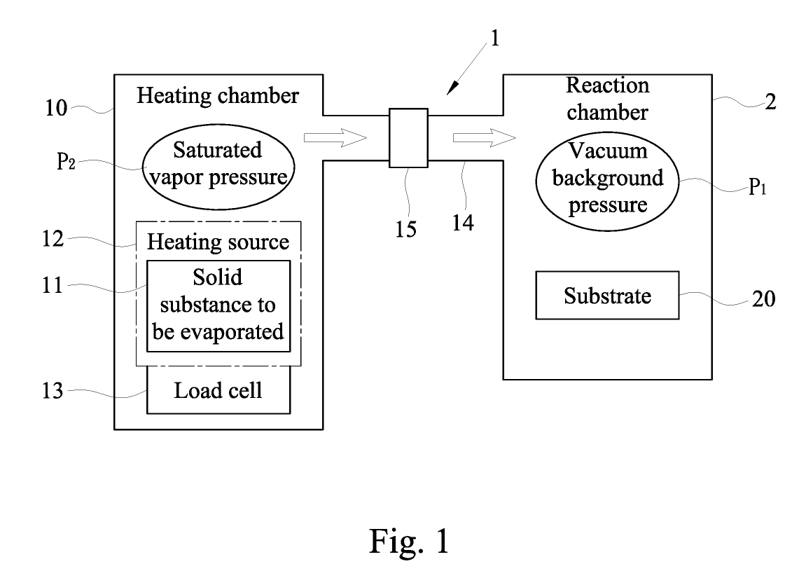

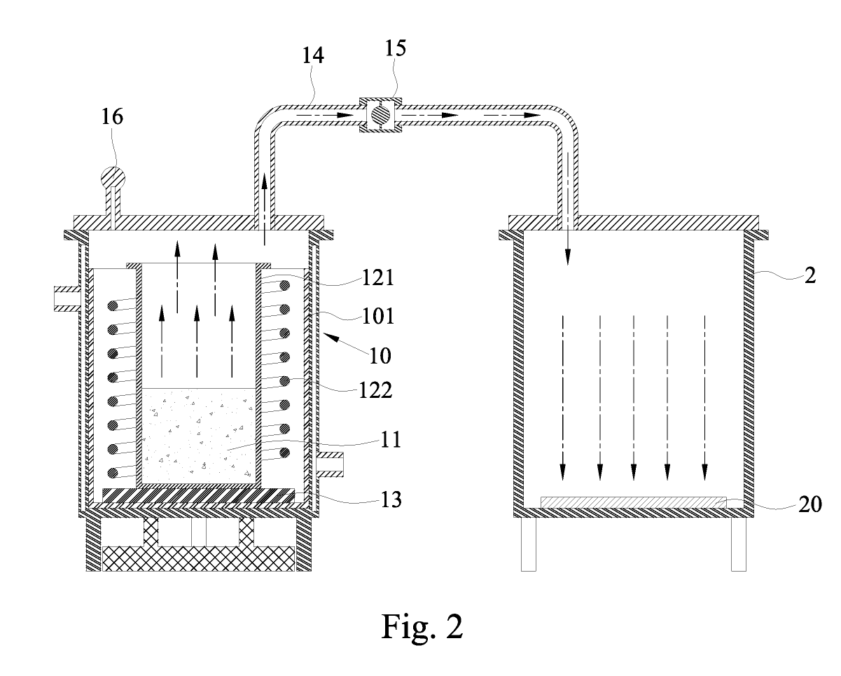

With reference to FIGS. 1, 2, 3, 4 and 5 for a block diagram showing the flow of a preferred embodiment of the present invention, a schematic view of an apparatus, a graph of reduced weight versus time of a solid substance to be evaporated at different set values of a proportion regulating valve in accordance with a preferred embodiment of the present invention, a graph of diffusion depth of a solid substance to be evaporated versus time during the process of preparing thin films in accordance with a preferred embodiment of the present invention, and a schematic view of the reproducibility of the proportion S/(Se+S) during the preparation of thin films in accordance with a preferred embodiment of the present invention respectively, this preferred embodiment discloses an apparatus for quantifying the amount of evaporation deposition of a solid substance 1, connected to a reaction chamber 2 and provided for performing an evaporation deposition process of a substrate 20, and the reaction chamber 2 has a vacuum background pressure P₁ therein. The apparatus 1 comprises a heating chamber 10, a solid substance to be evaporated 11, a heating source 12 and a load cell 13.

The heating chamber 10 is connected to the reaction chamber 2 through a pipeline 14. The solid substance to be evaporated 11 and the heating source 12 are disposed in the heating chamber 10, and the load cell 13 is connected to a crucible 121 in the heating chamber 10 through a vacuum bellow, and the heating source 12 I provided for heating the solid substance to be evaporated 11 to evaporate and form a reaction gas, and the reaction gas flows towards the reaction chamber 2 through the pipeline 14. The load cell 13 is provided for carrying and simultaneously detecting the reduced weight of the solid substance to be evaporated 11 per unit time is equal to the mass flow of the reaction gas. When the solid substance to be evaporated 11 is heated to an vapor state to form the reaction gas, the heating chamber 10 reaches a saturated vapor pressure P₂ greater than the vacuum background pressure P₁, so that the reaction gas continues to flow along the pipeline 14 stably towards the reaction chamber 2 to perform an evaporation deposition of the substrate, and the load cell 13 effectively quantifies the mass flow of the reaction gas formed by evaporating the solid substance to be evaporated 11 to ensure that the reaction gas stably flows towards the reaction chamber 2. In other words, in the evaporation deposition process, the apparatus 1 uses the load cell 13 to detect the reduced weight of the solid substance to be evaporated 11 per unit time, so as to learn the status of the thin film formed by the evaporation deposition, and the reaction gas is maintained to flow stably towards the reaction chamber 2 to improve the quality of the manufactured thin film. Wherein, the heating chamber 10 is a double-deck chamber with a water cooling function to prevent the heating chamber 10 from being overheated, and a thermal insulation layer 101 is installed in the heating chamber 10 for effectively isolating and preventing the heat of the heating source 12 from being conducted to the heating chamber 10.

Preferably, the apparatus for quantifying the amount of evaporation deposition of a solid substance 1 further comprises a proportion regulating valve 15 installed at the pipeline 14 for regulating the mass flow of the reaction gas passing into the reaction chamber 2 to control the amount of evaporation deposition of the solid substance to be evaporated 11. Wherein, the proportion regulating valve 15 does not directly control the mass flow of the reaction gas, but adopts the concept of proportion to adjust the mass flow of the reaction gas. In other words, the proportion regulating valve 15 is provided for adjusting the percentage of the reaction gas entering into the reaction chamber 2 instead of adjusting the mass flow value. The apparatus for quantifying the amount of evaporation deposition of a solid substance 1 can measure the reduced weight of the solid substance to be evaporated 11 per unit time detected by the load cell 13 during the process. If the proportion regulating valve 15 is adjusted to be greater or smaller, the reduced weight of the solid substance to be evaporated 11 per unit time will be increased or decreased respectively. To cope with the requirements of the evaporation deposition process, the proportion regulating valve 15 is adjusted to learn the change of the reduced weight of the solid substance to be evaporated 11 per unit time and understand the status of the reaction gas in the current process. For example, the proportion set by the proportion regulating valve 15 for the process may be 10%, 20% or 30%, etc. Since the reduced weight of the solid substance to be evaporated 11 per unit time is equal to the mass flow of the reaction gas, therefore when the set proportion is increased (from 10% to 30%), then the reduced weight of the solid substance to be evaporated 11 per unit time will be increased accordingly, and vice verse, so as to fulfill the reaction gas status required by the process.

In this preferred embodiment, the heating source 12 includes a crucible 121 and a heater 122, and the crucible 121 is provided for containing the solid substance to be evaporated 11, and the heater 122 is installed on an outer side of the crucible 121 for heating the solid substance to be evaporated 11 to evaporate to form the reaction gas. Preferably, the heater 122 is in the shape of a coil and installed around the outer periphery of the crucible 121, and the load cell 13 is installed at the bottom of the crucible 121 for simultaneously detecting the weight of the solid substance to be evaporated 11. However, this arrangement is an example used for illustrating the present invention, but not intended for limiting the scope of the invention.

Since the saturated vapor pressure P₂ is maintained to be greater than the vacuum background pressure P₁, and the reaction gas can flow from the pipeline 14 towards the reaction chamber 2, therefore the apparatus for quantifying the amount of evaporation deposition of a solid substance 1 may further install a manometer 16 at the heating chamber 10 for detecting the status of the saturated vapor pressure P₂ to ensure that the reaction gas can continue to flow towards the reaction chamber 2 for the process.

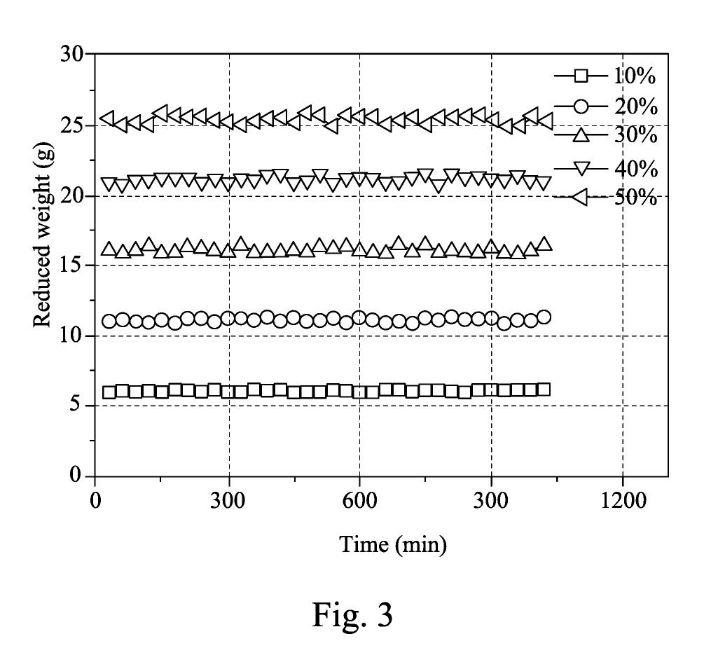

The present invention is applied in evaporation deposition for manufacturing an absorption layer of a solar cell as described below. The solid substance to be evaporated 11 may be sulfur (S) or selenium (Se) deposited on the substrate 20 to manufacture and form a CIGS or CIGSS thin film. In addition, the apparatus for quantifying the amount of evaporation deposition of a solid substance 1 of the present invention is applied in an evaporation deposition process of a CIGSS thin film. In the process, 30000 g of the solid substance to be evaporated 11 in form of particles is placed in the crucible 121, and the solid substance to be evaporated 11 is sulfur (S), and the set temperature of the heater 122 is 300° C. The substrate 10 is a glass substrate with a thickness of 3 mm and an area of 30 cm×30 cm, and coated with a 500 nm metal precursor. The vacuum background pressure P₁ of the reaction chamber 2 is controlled to be 1×10⁻⁶ Torr by a vacuum pump, and the process time is set to be 10-1050 minutes. Within the process time, the load cell 13 is provided for simultaneously detecting different portions set by the proportion regulating valve 15, and the reduced weight of the solid substance to be evaporated 11 per unit time is show in FIG. 3. In FIG. 3, when the proportion set by the proportion regulating valve 15 is increased from 10% to 50%, the reduced weight of the solid substance to be evaporated 11 per unit time increases with the increase of the proportion set by the proportion regulating valve 15, and the reduced weight of the solid substance to be evaporated 11 per unit time is very stable and almost remains unchanged, and such reduced weight will not decrease with the drop of the liquid level after the solid substance to be evaporated 11 is evaporated, so as to maintain an equal loss status. It shows that the reaction gas flows into the reaction chamber 2 to perform an evaporation deposition process with very stable mass flow and condition, so that the thin film manufactured by the apparatus for quantifying the amount of evaporation deposition of a solid substance 1 has the features of high uniformity and stable quality. For example, when the proportion set by the proportion regulating valve 15 falls at 10%, the solid substance to be evaporated 11 can be detected by the load cell 13 to learn that the reduced weight per unit time is 6 g, and when the proportion set by the proportion regulating valve 15 falls at 50%, the solid substance to be evaporated 11 can be detected by the load cell 13 to learn that the reduced weight per unit time is 25 g, which is greater than the reduced weight of the solid substance to be evaporated 11 when the proportion of the proportion regulating valve 15 is set to 10%. Regardless of which proportion, the reduced weight of the solid substance to be evaporated 11 per unit time tends to be a constant and very stable. In the application of the apparatus 1 for manufacturing a solar cell absorption layer, other evaporation deposition materials such as copper (Cu), indium (In), gallium (Ga), etc can be used for the evaporation deposition or co-evaporation deposition, but this is not the major technical characteristic of the present invention, and thus will not be described here. The material such as sulfur (S) or selenium (Se) can be evaporated by the apparatus 1 to manufacture the thin film. It is noteworthy that the drawings are provided for the purpose of illustrating the technical characteristics of the present invention, but not intended for limiting the scope of the invention.

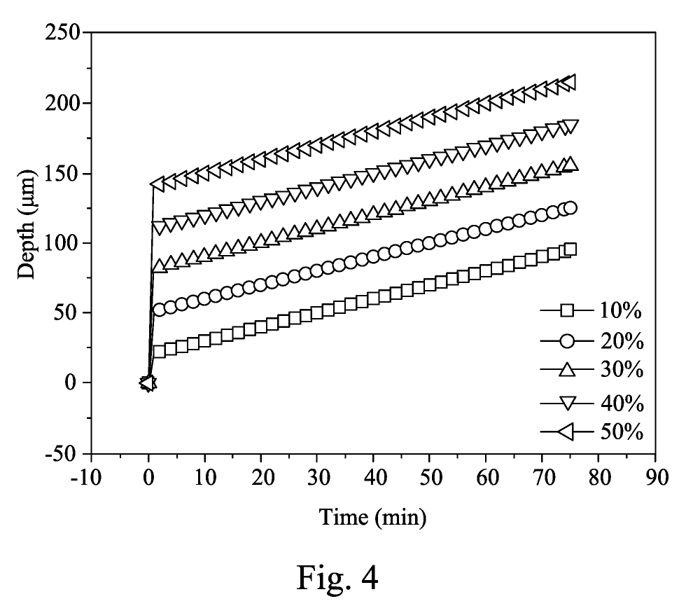

In addition, the depth distribution status of the solid substance to be evaporated 11 in CIGSS thin film at different process conditions are measured, and the results are shown in FIG. 4. In FIG. 4, when the gas pressure control valve receives the same vacuum background pressure and the vacuum background pressure is increased with the process time, the diffusion depth of the solid substance to be evaporated 11 increases with the proportion set by the proportion regulating valve 15 and diffuses stably towards the interior of the CIGSS thin film. To verify that this process can effectively improve the conversion efficiency of a solar cell, if the proportion set by the proportion regulating valve 15 is 10-30%, and the process time is 5-30 minutes, the conversion efficiency of the CIGSS solar cell under the aforementioned conditions can be increased from 10% to 14%, and this shows that the proportion regulating valve 15 can be used to effectively control the diffusion depth of the thin film with respect to the solid substance to be evaporated 11 for the thin film manufactured by the apparatus 1, and the diffusion is performed stably towards the thin film, so that the manufactured thin film have very uniform and excellent quality. In the evaporation deposition process, the status of the reaction gas has a significant effect on the quality of the manufactured thin film, and the aforementioned experiment results show that the apparatus for quantifying the amount of evaporation deposition of a solid substance 1 of the present invention has the feature of reducing the weight of the solid substance to be evaporated 11 very stably. In other words, the reaction gas is regarded as a stable mass flow, and the diffusion of the solid substance to be evaporated 11 is also stable, and thus the uniformity of the depth distribution of compositions in the thin film is very high, and the reaction gas used for the process of the present invention is stable, and the thin film with a high composition uniformity can be manufactured.

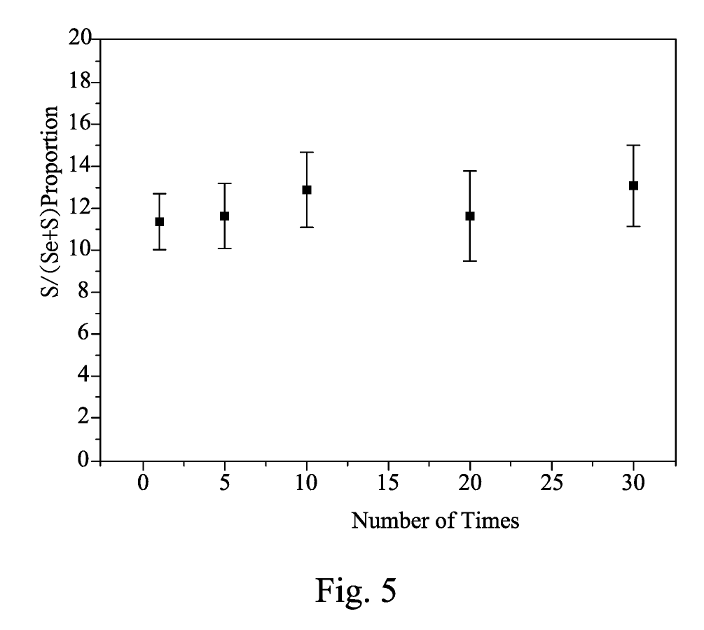

To verify that the thin film formed by evaporation deposition by the apparatus for quantifying the amount of evaporation deposition of a solid substance 1 has a stable quality, and another group of experiments are performed for testing and measuring repeatedly to show its reproducibility. In the process, 10000 g of the solid substance to be evaporated 11 is put into the crucible 121, wherein the solid substance to be evaporated 11 is sulfur (S), and the heater 122 is set to a temperature of 300° C., and the substrate 20 is a glass substrate with a thickness of 3 mm and an area of 30 cm×30 cm, and coated with a 1500 nm CIGS thin film. The vacuum background pressure P₁ of the reaction chamber 2 is controlled to 1×10⁻⁶ Torr. In this experiment, the proportion set by the proportion regulating valve 15 is 10%, and when the heating source 12 heats up and evaporates the solid substance to be evaporated 11 to form the reaction gas, the saturated vapor pressure P₂ of the heating chamber 10 is greater than the vacuum background pressure P₁, so that the reaction gas flows from the pipeline 14 into the reaction chamber 2, and when the reaction gas passes into the reaction chamber 2, a stable working pressure is maintained at 400 m Torr, and N₂ gas is introduced, so that the total working pressure of the reaction chamber 2 reaches 650 mTorr, and the temperature of the reaction chamber 2 is set to 550° C., and the process time is 20 minutes. The aforementioned experiment and measurement are repeated for 1-30 times, and the compositions of the manufactured CIGSS thin film are analyzed and verified, and the result of the proportion of S/(Se+S) obtained from the composition analysis is shown in FIG. 5. In FIG. 5, the proportion of S/(Se+S) in the thin film is very stable in the same process conditions, and it shows that the reproducibility of this experiment is excellent. In other words, the proportion of the composition in the thin film manufactured by the solid substance to be evaporated 11 by the apparatus 1 is very stable. In other words, the composition uniformity of the thin film is excellent, because the reaction gas introduced in the reaction chamber 2 has excellent stability, and the thin film manufactured by the solid substance to be evaporated 11 features stable proportion and excellent composition uniformity to prevent the thin film from lacking of a certain specific element. The apparatus 1 of the present invention definitely can supply the reaction gas stably to form a high-quality thin film.

With reference to FIGS. 1 to 5, the present invention discloses a method for quantifying the amount of evaporation deposition, comprising the steps of supplying a stable vapor to a reaction chamber 2 to perform an evaporation deposition process of a substrate 20 in the reaction chamber 2, and the reaction chamber 2 has a vacuum background pressure P₁. The method comprises the steps of installing a solid substance to be evaporated 11, a heating source 12 and a load cell 13, and the load cell 13 is coupled to a crucible in the heating chamber 10 through a vacuum bellow, and the heating chamber 10 is coupled to the reaction chamber 2 through a pipeline 14; so that the heating source 12 heats and evaporates the solid substance to be evaporated 11 to form a reaction gas, and the load cell 13 is provided for carrying and simultaneously detecting the weight of the solid substance to be evaporated 11, wherein the reduced weight of the solid substance to be evaporated 11 per unit time is equal to the mass flow of the reaction gas. When the solid substance to be evaporated 11 is evaporated to form the reaction gas, the heating chamber 10 reaches a saturated vapor pressure P₂ greater than the vacuum background pressure P₁, so that the reaction gas continues to stably flow along the pipeline 14 towards the reaction chamber 2 to perform an evaporation deposition of the substrate 20, and the load cell 13 effectively quantifies the mass flow of the reaction gas formed by evaporating the solid substance to be evaporated 11 to ensure that the reaction gas flows into the reaction chamber 2 stably. And because of the load cell continues measuring the mass of the solid substance, the generation speed of the reaction gas and the speed of the evaporation deposition can meet requirements.

Similarly, the pipeline 14 further has a proportion regulating valve 15 for regulating the mass flow of the reaction gas to cope with the process requirements. In other words, the proportion regulating valve 15 can change the reduced weight of the solid substance to be evaporated 11 per unit time. The heating source 12 includes a crucible 121 and a heater 122, and the crucible 121 is provided for containing the solid substance to be evaporated 11, and the heater 122 is installed to the outer side of the crucible 121 for heating and evaporating the solid substance to be evaporated 11 to form the reaction gas and simultaneously confirm that the saturated vapor pressure P₂ is greater than the vacuum background pressure P₁, so that the reaction gas continues to flow into the reaction chamber 2. The heating chamber 10 further has a manometer 16 for detecting the saturated vapor pressure P₂. And the present invention can receive the same vacuum background pressure by the gas pressure control valve in the process. Since other details and characteristics are the same as those described above, therefore they will not be repeated. The thin film manufactured by the method of the invention has the features of stable composition uniformity stable and high quality, and the process conditions and measurement results are shown in FIGS. 3-5.

In summation of the description above, the present invention discloses an apparatus and method for quantifying the amount of evaporation deposition of a solid substance, wherein the load cell is provided for simultaneously detecting the evaporation state of the solid substance to be evaporated to achieve the effect of quantifying the mass flow of the reaction gas in the process, so as to accurately control the status of the reaction gas in the manufacturing process, and the saturated vapor pressure in the heating chamber is greater than the vacuum background pressure of the reaction chamber, so that the reaction gas naturally flows towards the reaction chamber to maintain its stability, and the manufactured thin film has the features of excellent composition uniformity and high quality. The present invention further uses the proportion regulating valve to control the mass flow of the reaction gas and integrates the load cell and uses the reduced weight of the solid substance to be evaporated to simultaneously reflect whether or not the reaction gas flows into the reaction chamber according to the setting of the proportion regulating valve, so as to control the process effectively. Experiments show that the thin film manufactured by the apparatus and method for quantifying the amount of evaporation deposition of a solid substance of the present invention features a high uniformity and an excellent quality and effectively overcomes the drawback of unable to confirm and control the solid substance to be used as the evaporation deposition material.

The foregoing embodiments are merely illustrative of the features and effects of the present invention and are not intended to limit the scope of the essential technical aspects of the present invention. It will be apparent to those skilled in the art that the above-described embodiments may be modified and modified without departing from the spirit and scope of the invention. Accordingly, the scope of the present invention is to be accorded the scope of the appended claims.

In summation of the description above, the present invention improves over the prior art and complies with patent application requirements, and thus is duly filed for patent application.

What is claimed is:

1. An apparatus for quantifying the amount of evaporation deposition of a solid substance, connected to a reaction chamber and provided for performing an evaporation deposition process of the substance therein, and the reaction chamber has a vacuum background pressure therein, and the apparatus for quantifying the amount of evaporation deposition of a solid substance comprising:
a heating chamber, connected to the reaction chamber through a pipeline;
a solid substance to be evaporated, disposed in the heating chamber;
a heating source, installed in the heating chamber, and provided for heating the solid substance to be evaporated to evaporate and form a reaction gas, and flowing the reaction gas to the reaction chamber through the pipeline; and
a load cell, installed outside the heating chamber, for carrying the solid substance to be evaporated and simultaneously detecting a weight of the solid substance to be evaporated, wherein an amount of the weight loss of the solid substance to be evaporated per unit time is equal to a mass flow of the reaction gas;
wherein, when the solid substance to be evaporated is heated to a vapor state to form the reaction gas, the heating chamber has a saturated vapor pressure greater than the vacuum background pressure, so that the reaction gas continues to flow along the pipeline towards the reaction chamber to perform an evaporation deposition of the substrate, and the load cell simultaneously detects a mass change of the solid substance to be evaporated to effectively quantify a gas mass flow of the reaction gas formed after the solid substance to be evaporated is evaporated, and control the reaction gas flow flowing into the reaction chamber and the film deposition effect.

2. The apparatus for quantifying the amount of evaporation deposition of a solid substance according to claim 1, further comprising a proportion regulating valve installed at the pipeline for regulating the mass flow of the reaction gas passing into the reaction chamber.

3. The apparatus for quantifying the amount of evaporation deposition of a solid substance according to claim 1, wherein the heating chamber has a thermal insulation layer disposed therein.

4. The apparatus for quantifying the amount of evaporation deposition of a solid substance according to claim 1, wherein the heating source includes a crucible and a heater.

5. The apparatus for quantifying the amount of evaporation deposition of a solid substance according to claim 1, further comprising a manometer installed at the heating chamber for detecting the saturated vapor pressure.

6. The apparatus for quantifying the amount of evaporation deposition of a solid substance according to claim 1, further comprising a gas pressure control valve installed at the reaction chamber for adjusting a vacuum background pressure of the reaction chamber.

7. A method for quantifying the amount of evaporation deposition, for supplying a stable reaction gas to a reaction chamber to perform an evaporation deposition process of a substrate in the reaction chamber, and the reaction chamber having a vacuum background pressure, comprising the steps of:
providing a heating chamber having a heater and a crucible for carrying a solid substance to be evaporated, and the heating chamber having a load cell installed outside the heating chamber, and the load cell being coupled to the crucible in the heating chamber through a vacuum bellow for measuring a mass of the solid substance to be evaporated, and the heating chamber being coupled to the reaction chamber through a pipeline; the heater heating the crucible, such that the solid substance to be evaporated is evaporated to form the reaction gas, and when an interior of the heating chamber reaches a saturated vapor pressure greater than the vacuum background pressure, the reaction gas continues to flow along the pipeline towards the reaction chamber to perform an evaporation deposition of the substrate, and the load cell continues measuring the mass of the solid substance to be evaporated to ensure the generation speed of the reaction gas and the speed of the evaporation deposition can meet requirements.

8. The method for quantifying the amount of evaporation deposition according to claim 7, wherein the pipeline further has a proportion regulating valve for regulating the mass flow of the reaction gas passing into the reaction chamber.

9. The method for quantifying the amount of evaporation deposition according to claim 7, wherein the heating chamber has a thermal insulation layer disposed therein for isolating the heat of the heating source from conducting to the heating chamber.

10. The method for quantifying the amount of evaporation deposition according to claim 7, wherein the heating source includes a crucible and a heater, and the crucible is provided for containing the solid substance to be evaporated, and the heater is installed at the outer side of the crucible for heating the solid substance to be evaporated to evaporate the solid substance to be evaporated to form the reaction gas.

11. The method for quantifying the amount of evaporation deposition according to claim 7, wherein the reaction chamber further has a gas pressure control valve for adjusting a vacuum background pressure of the reaction chamber.

12. The method for quantifying the amount of evaporation deposition according to claim 7, wherein the heating chamber further has a manometer for detecting the saturated vapor pressure.
